(19) United States
(12) Patent Application Publication
(10) Pub. No.: US 2006/0038596 A1
(43) Pub. Date: Feb. 23, 2006

(54) Delay locked loop circuitry and method for optimizing delay timing in mixed signal systems

(76) Inventor: Binan Wang, Tucson, AZ (US)

Correspondence Address: TEXAS INSTRUMENTS INCORPORATED, P O BOX 655474, M/S 3999, DALLAS, TX, 75265, US

(21) Appl. No.: 10/921,001

(22) Filed: Aug. 18, 2004

(51) Int. Cl. H03L 7/06

(52) U.S. Cl. 327/158

(57) ABSTRACT

A mixed signal system includes a digital circuit (17) clocked by a digital clock signal, an analog circuit (18) clocked by an analog clock signal, and clock generation circuitry (15) including a delay locked loop (20) including a N-cell delay line (21) having an input for receiving a reference clock signal and a plurality of delay outputs (22), and a multiplexer (30) having a plurality of inputs coupled to the plurality of delay outputs (22), respectively. A selection signal (34) causes the multiplexer (30) to couple a selected one of the delay outputs (22) to an output (32) of the multiplexer (30) so as to cause the analog clock signal and the digital clock signal to be sufficiently skewed from each other to minimize an inaccuracy in the analog circuit (18) caused by a noise glitch associated with the digital clock signal.

### BACKGROUND OF THE INVENTION

The present invention relates generally to high-performance monolithic (i.e., integrated circuit) mixed signal systems including digital and also including analog circuitry, such as a low noise delta sigma analog-to-digital converter (ADC) and/or a digital-to-analog-converter (DAC). The invention relates more particularly to a method and circuit for minimizing the degradation of analog signals due to noise caused by digital signals in a monolithic mixed signal system.

In such high-performance monolithic mixed signal systems, transitions of digital signals associated with digital circuitry often create a noise or disturbance (sometimes referred to as a “glitch”) that is superimposed on ground conductors and/or supply voltage conductors and/or signal conductors and/or the integrated circuit chip substrate. Such noise or interference may degrade analog circuit performance, depending on the magnitude and timing of the glitch. The timing of certain events in some analog circuitry is very critical, for example in some sampled data systems including switched capacitor circuitry wherein analog signals are acquired at certain discrete moments.

FIG. 1A shows a typical switched capacitor circuit 2 including a switch 80 having one terminal coupled to an analog input voltage Vin and another terminal coupled by conductor 81 to one terminal of a capacitor C and to one terminal of a switch 82. The other terminal of capacitor C is connected to ground conductor 3. The other terminal of switch 82 is connected to the (−) input of an integrating amplifier 83 and to one terminal of an integrating capacitor 84. The other terminal of integrating capacitor 84 is connected to the output of amplifier 83. Switches 80 and 82 are controlled by analog clock signals φ1 and φ2, shown in the timing diagram of FIG. 1B. In operation, Vin is sampled onto capacitor C while switch 80 is closed during a pulse of φ1. Later, during a pulse of φ2, switch 82 is closed so that the charge corresponding to Vin stored on capacitor C is redistributed onto integrating capacitor 84.

If a falling edge of a pulse of an analog clock signal that controls switch 80 occurs during the noise glitch 6, it could cause interference such as a ground bounce voltage to be superimposed the value of Vin that has just been sampled onto capacitor C as described above, and could cause inaccurate analog circuit operation. More specifically, in FIG. 1B, a positive-going transition 5 of a digital clock signal DIGITAL CLOCK in a monolithic mixed system of the type referred to above may cause noise “glitch” 6 on ground conductor 3 in FIG. 1A (and/or a power supply conductor, signal conductor and/or the substrate of the integrated circuit chip). If the noise glitch 6 on ground conductor 3 occurs during the period when switch 80 is closed, the voltage of noise glitch 6 could be superimposed on the value of Vin across capacitor C. If switch 80 is opened by the trailing edge 7A of pulse 7 of analog clock signal φ1 before noise glitch 6 has settled, an erroneous value of Vin is stored on capacitor C and subsequently redistributed onto integrating capacitor 84 when φ2 closes switch 82. This may result in unacceptable inaccuracy of the voltage produced by the output of integrating amplifier 83. (Also, digital noise may be coupled to capacitor C through the chip substrate or other nearby metal conductors such as a power supply conductor or a signal conductor and superimpose errors on analog signals in generally the same way as described above.) Those skilled in the art know that for the digital output of a high-resolution delta sigma ADC to be accurate, it is necessary to keep “analog front end” circuitry as free as possible from interference. For example, even a error as low as a few microvolts can cause unacceptable error in a 24-bit ADC and substantially decrease the SNR (signal to noise ratio) of a system including the delta sigma ADC.

U.S. Pat. No. 4,746,899, issued May 24, 1988 and entitled “Method for Reducing Effects of Electrical Noise in an Analog-to-Digital Converter”, discloses one common approach to reducing the above-mentioned degradation of analog circuit performance by skewing the analog timing/clock signals away from transitions of digital clock signals by generating a digital clock signal using a delayed version of the analog clock signal.

If a master clock signal is available having a higher frequency than the operating digital and analog clock rate of the mixed signal system, another approach can be used which involves subdividing the master clock signal into multiple clock signals having different timing for the analog and digital circuitry. With that approach, critical analog clock signal timing is skewed away from the digital clock signal transitions, making it less susceptible to digital noise coupling. The timing diagram of FIG. 2 illustrates an example of this technique wherein a signal MASTER CLOCK is six times faster than both an analog clock signal ANALOG CLOCK and a digital clock signal DIGITAL CLOCK. However, this approach is not viable in systems wherein the master clock signal is used directly for clocking either the digital circuitry or the analog circuitry. A phase locked loop could usually be used to generate a higher speed master clock from the main master clock and thereby allow use of the above-described multiple phase clock signal subdividing scheme, but that approach tends to increase power consumption of the monolithic integrated circuit and leads to increased jitter of the derived high-speed master clock signal. This can cause degradation of the signal-to-noise ratio (SNR) in the system.

Another known technique for avoiding the above-mentioned degradation of analog circuit performance due to digital noise coupling is to use simple delay cells to skew the analog clock signal with respect to the digital clock signal. FIG. 3 illustrates such a simple delay cell 10 which includes a pair of sequentially coupled inverters 11-1 and 11-2 having outputs which may be connected to capacitors 12-1 and 12-2, respectively. A digital clock signal IN is applied to the input of inverter 11-1, and the delayed or skewed analog output clock signal OUT is produced at the output of inverter 11-2. Unfortunately, the delay times of such simple delay cells are very dependent on integrated circuit chip temperature variations, semiconductor manufacturing process variations, and power supply variations, and therefore tend to be quite inaccurate.

Even if the delay time can be accurately controlled, it may be very difficult to determine by means of calculations or computer simulations/analysis what constitutes an adequate or optimal amount of delay or skew needed between a digital clock signal and an analog clock signal in a monolithic mixed signal system to avoid degradation of analog signals therein due to digital noise coupling.

Thus, there is an unmet need for an improved method and circuit for minimizing degradation of analog signals due to digital noise coupling in monolithic mixed signal systems.

There also is an unmet need for a way of avoiding problems caused by degradation of analog signals due to digital noise coupling in monolithic mixed signal systems wherein the master clock signal is used directly for clocking the digital circuitry or the analog circuitry.

There also is an unmet need for a way of avoiding degradation of analog signals due to digital noise coupling in monolithic mixed signal systems without substantially increasing power consumption of the integrated circuit chip.

There also is an unmet need for a way of avoiding degradation of analog signals due to digital noise coupling in a monolithic mixed signal system without introducing excessive clock jitter that results in reduced performance of the monolithic mixed signal system.

There also is an unmet need for a way of avoiding degradation of analog signals due to digital noise coupling in a mixed signal system irrespective of variations in integrated circuit chip temperature and irrespective of variations in the semiconductor manufacturing process.

There also is an unmet need for a convenient way of optimally selecting a derived clock signal in a monolithic mixed signal system so as to avoid degradation of analog signals due to digital noise coupling in the monolithic mixed signal system.

### SUMMARY OF THE INVENTION

It is an object of the invention an improved method and circuit for minimizing degradation of analog signals due to digital noise coupling in monolithic mixed signal systems.

It is another object of the invention to provide a way of avoiding problems caused by degradation of analog signals due to digital noise coupling in monolithic mixed signal systems wherein the master clock signal is used directly for clocking the digital circuitry or the analog circuitry.

It is another object of THE invention to provide a way of avoiding degradation of analog signals due to digital noise coupling in monolithic mixed signal systems without substantially increasing power consumption of the integrated circuit chip.

It is another object of the invention to provide a way of avoiding degradation of analog signals due to digital noise coupling in a monolithic mixed signal system without introducing excessive clock jitter that results in reduced performance of the monolithic mixed signal system.

It is another object of the invention to provide a way of avoiding degradation of analog signals due to digital noise coupling in a mixed signal system irrespective of variations in integrated circuit chip temperature and irrespective of variations in the semiconductor manufacturing process.

It is another object of invention to provide a convenient way of optimally selecting a derived clock signal in a monolithic mixed signal system so as to avoid degradation of analog signals due to digital noise coupling in the monolithic mixed signal system.

Briefly described, and in accordance with one embodiment, the present invention provides a way of operating a mixed signal system (1 or 1A) in an integrated circuit chip to avoid degradation of an analog signal due to noise caused by a digital signal, the mixed signal system (1 or 1A) including a digital circuit (1) including a clock input for receiving a digital clock signal (DIGITAL CLOCK) and also including an analog circuit (18) including a clock input for receiving an analog clock signal (ANALOG CLOCK) wherein a digital signal associated with the digital circuitry (17) causes coupling of a noise glitch (13A) to the analog circuit (18). A reference clock signal (CKref) is applied to a clock input of a delay locked loop (20) having a plurality of delay outputs (22). One of the delay outputs (22) is coupled to an output (32) of the delay locked loop (20). The reference clock signal (CKref) functions as one of the digital clock signal (DIGITAL CLOCK) and the analog clock signal (ANALOG CLOCK). The output (32) of the delay locked loop (20) produces the other of the digital clock signal (DIGITAL CLOCK) and the analog clock signal (ANALOG CLOCK), the analog clock signal (ANALOG CLOCK) and the digital clock signal (DIGITAL CLOCK) being sufficiently skewed from each other to produce best operating results in the analog circuit (18) despite the coupling of the noise glitch (13A) thereto.

In one embodiment, the invention provides a way of operating a mixed signal system (1 or 1A) in an integrated circuit chip to avoid degradation of an analog signal due to noise caused by a digital signal, the mixed signal system (1 or 1A) including a digital circuit (1) including a clock input for receiving a digital clock signal (DIGITAL CLOCK) and also including an analog circuit (18) including a clock input for receiving an analog clock signal (ANALOG CLOCK) wherein a digital signal associated with the digital circuitry (17) causes coupling of a noise glitch (13A) to the analog circuit (18). A reference clock signal (CKref) is applied to a clock input of a delay locked loop (20) having a plurality of delay outputs (22). The plurality of delay outputs (22) are coupled to a plurality of inputs, respectively, of a multiplexer (30) having a selection input (34) for receiving a selection signal for causing the multiplexer (30) to couple a selected one of the delay outputs (22) to an output (32) of the multiplexer (30). The reference clock signal (CKref) functions as one of the digital clock signal (DIGITAL CLOCK) and the analog clock signal (ANALOG CLOCK). The output (32) of the multiplexer (30) produces the other of the digital clock signal (DIGITAL CLOCK) and the analog clock signal (ANALOG CLOCK). A value of the selection input signal (34) of the multiplexer (30) is selected which causes the analog clock signal (ANALOG CLOCK) and the digital clock signal (DIGITAL CLOCK) to be sufficiently skewed from each other to produce best operating results in the analog circuit (18) despite the coupling of the noise glitch (13A) thereto.

The described mixed signal system includes a digital circuit (1) including a clock input for receiving a digital clock signal (DIGITAL CLOCK) an analog circuit (18) including an input for receiving an analog clock signal (ANALOG CLOCK). The clock generation circuitry (15 or 15A) The digital circuitry (17) causes coupling of a noise glitch (13A) to the analog circuit (18). The clock generation circuitry includes a delay locked loop (20) including a N-cell delay line (21) having an input for receiving a reference clock signal and a plurality of delay outputs (22) and a multiplexer (30) having a plurality of inputs coupled to the plurality of delay outputs (22), respectively, and a selection input (34) for receiving a selection signal for causing the multiplexer (30) to couple a selected one of the delay outputs (22) to an output (32) of the multiplexer (30). The reference clock signal (CKref) is utilized as one of the digital clock signal (DIGITAL CLOCK) the analog clock signal (ANALOG CLOCK), and the output (32) of the multiplexer (30) is used as the other of the digital clock signal (DIGITAL CLOCK) the analog clock signal (ANALOG CLOCK). The selection input signal (34) of the multiplexer (30) is selected so as to cause the analog clock signal (ANALOG CLOCK) and the digital clock signal (DIGITAL CLOCK) to be sufficiently skewed from each other to produce best operating results in the analog circuit (18) despite the coupling of the noise glitch (13A) thereto.

### BRIEF DESCRIPTION OF THE DRAWINGS

FIG. 1A is a diagram of a switched capacitor circuit that is useful in explaining a noise interference problem in a monolithic mixed signal system.

FIG. 1B is a signal timing diagram useful in explaining a noise interference problem in the circuit shown in FIG. 1A.

FIG. 2 is a timing diagram useful in explaining one prior art approach to dealing with the noise interference problem solved by the present invention.

FIG. 3 is a schematic diagram of a typical delay cell sometimes used for skewing an analog clock signal with respect to a digital clock signal to avoid the noise interference problem solved by the present invention.

FIG. 4 is a block diagram of an embodiment of the present invention.

FIG. 5 is a more detailed block diagram of the embodiment of shown in FIG. 4.

FIG. 6 is a schematic diagram of a typical delay cell used in the delay locked loop circuit 21 included in FIG. 5.

FIG. 7 is a timing diagram useful in explaining operation of the embodiment of the invention shown in FIG. 5.

FIG. 8A is a block diagram of a monolithic integrated circuit including a mixed signal system and also including analog clock signal generating circuitry of the present invention.

FIG. 8B is a block diagram of a monolithic integrated circuit including a mixed signal system and also including digital clock signal generating circuitry of the present invention.

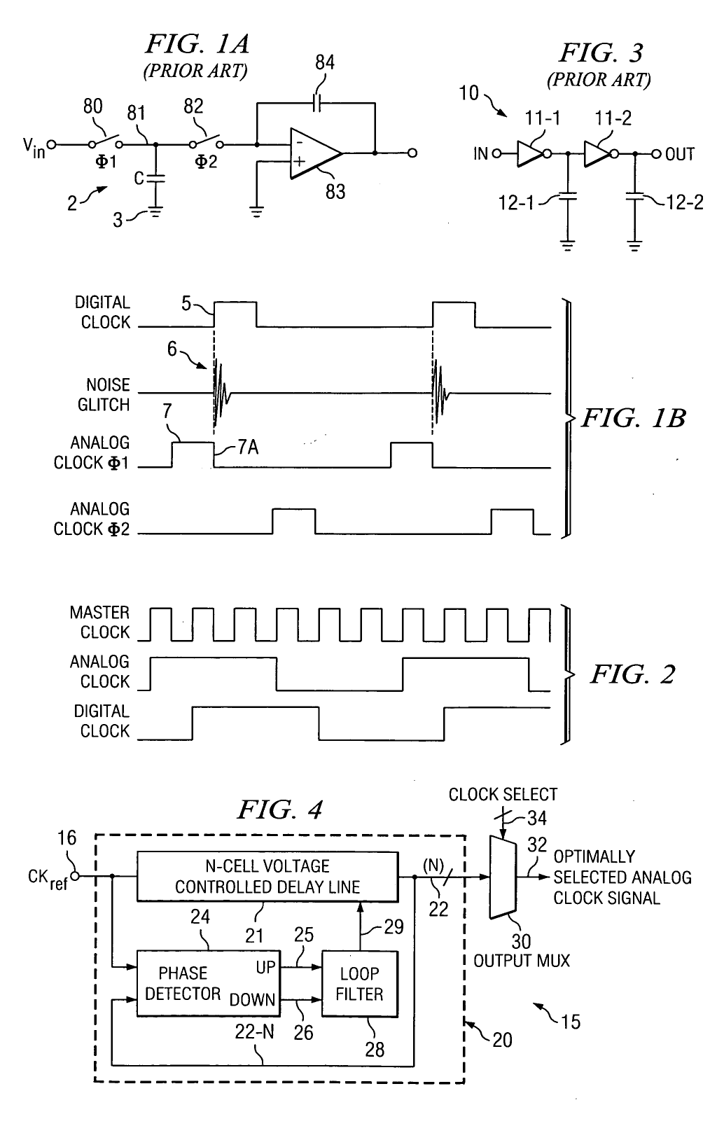

### DETAILED DESCRIPTION OF THE PREFERRED EMBODIMENTS

The described embodiment of the invention provides a practical way of selecting an optimum amount of the delay between an analog clock signal and a digital clock signal so as to reduce or minimize degradation of analog signals in a mixed signal systems due to noise caused by digital signals therein, wherein the delay is insensitive to temperature variations and process variations.

Referring to FIG. 4, an analog clock generation circuit 15 of the present invention includes a conventional delay locked loop (DLL) circuit 20 and an output multiplexer circuit 30. DLL circuit 20 includes a voltage controlled delay line 21 having N delay cells, a phase detector 24, and a loop filter 28. An input clock signal CKref is applied by conductor 16 to an input of the first delay cell 40-1 of controlled delay line 21 and also to a first input of phase detector 24. The outputs of the various N delay cells of controlled delay line 21 are connected to various inputs, respectively, of an output multiplexer 30. The output of the last delay cell 40-N of controlled delay line 21 is connected by conductor 22-N to a second input of phase detector 24. Phase detector 24 produces a signal UP on conductor 25 and applies it to a first input of loop filter 28, and also produces a signal DOWN on conductor 26 and applies it to a second input of loop filter 28. Loop filter 28 produces a delay control signal on conductor 29, which is connected to or coupled by a voltage-to-current converter to the delay control inputs of all of the N delay cells in delay line 21.

In accordance with the present invention, a digital clock select signal CLOCK SELECT is applied by means of conductors 34 to the input signal selection inputs, respectively, of output multiplexer 30 so as to cause multiplexer 30 to couple a selected one of delay line output conductors 22 to multiplexer output conductor 32. In accordance with the present invention, an “optimally selected” analog clock signal on one of delay cell outputs 22-1, 22-2 . . . 22-N is produced on multiplexer output conductor 32. Note that those skilled in the art can readily provide variety of practical implementations of phase detector 24, loop filter circuit 28, and multiplexer 30.

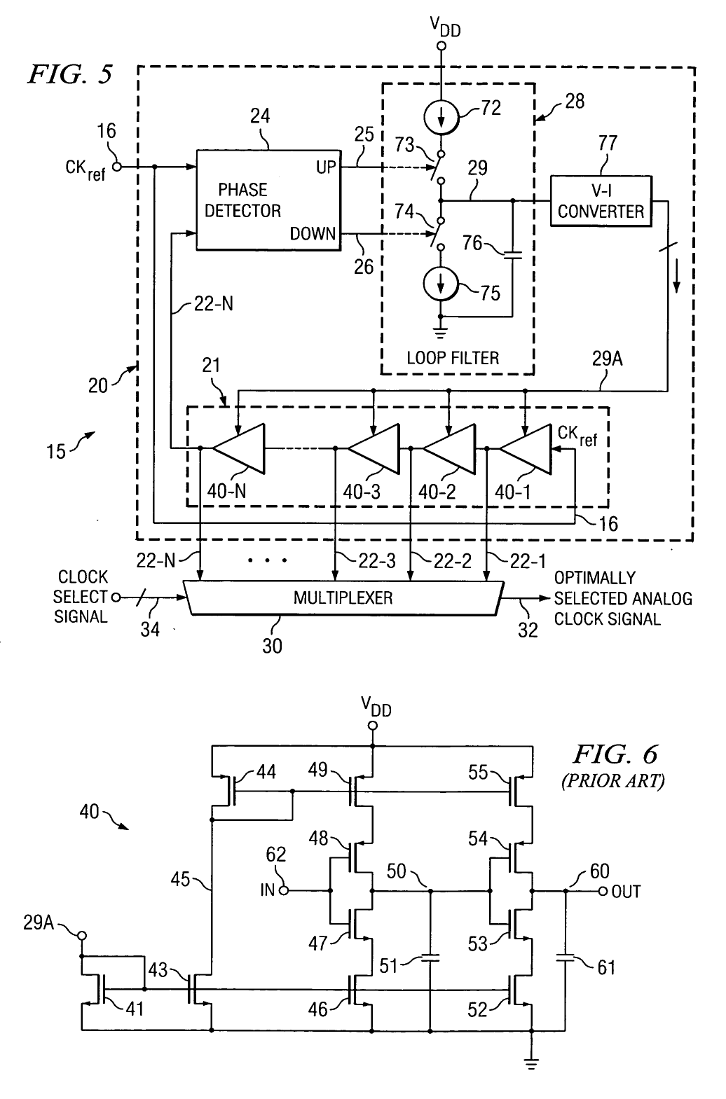

FIG. 5 shows a more detailed implementation of the analog clock generation circuitry 15 of FIG. 4. Referring to FIG. 5, loop filter 28 is a charge pump circuit of the type commonly used in delay locked loop circuits and phase locked loop circuits. Loop filter 28 is schematically illustrated as including a first current source 72 coupled between power supply voltage VDD and one terminal of a switch 73, the other terminal of which is connected to delay control conductor 29. The voltage produced by loop filter 28 on delay control conductor 29 is applied to an input of conventional voltage-to-current converter circuitry 77, outputs of which produce multiple corresponding control currents through a control current conductor 29A of each current-controlled delay cell, respectively. See subsequently described FIG. 6. In a practical implementation, each delay cell can be considered to include its own voltage-to-current converter circuit 77.

Switch 73 is controlled by the UP signal on conductor 25. A capacitor 76 is coupled between delay control conductor 29 and ground. A second switch 74 is connected between delay control conductor 29 and one terminal of a second current source 75, the other terminal of which is connected to ground. Switch 74 is controlled by the DOWN signal on conductor 26.

Delay line 21 is made up by cascading multiple identical delay cells 40 (although in some cases the delay cells might not all be identical). The delay of each delay cell is set by the delay control voltage on conductor 29. The output of loop filter 28 provides the delay control voltage on delay control conductor 29.

As shown in FIG. 5, delay line 21 includes N delay cells 40-1, 40-2 . . . 40-N, wherein each delay cell includes a delay control input connected to delay control conductor 29, as shown in subsequently described FIG. 6. The output of the first delay cell 40-1 is connected by conductor 22-1 to the input of the second delay cell 40-2 and to the first input of multiplexer 30. Similarly, the output of the second delay cell 40-2 is connected by conductor 22-2 to the input of the third delay cell 40-3 and to the second input of multiplexer 30, and so forth. (In some cases, fewer than all of the delay cell outputs be connected to multiplexer 30.) The input of first delay cell 40-1 is connected to conductor 16 to receive the reference clock signal CKref. The output 22-N of the last delay cell 40-N is connected by conductor 22-N to the second input of phase detector 24.

FIG. 6 shows a conventional CMOS implementation 40 of each of delay cells 40-1 through 40-N. Delay control conductor 29 is connected to the gate and drain of a N-channel current mirror input transistor 41 having its source connected to ground. The drain of transistor 41 is also connected to the gates of N-channel current mirror output transistors 43, 46, and 52, each of which has its source connected to ground. The drain of transistor 43 is connected by conductor 45 to the gate and drain of a P-channel current mirror input transistor 44 and to the gates of P-channel current mirror output transistors 49 and 55. The sources of transistors 44, 49 and 55 are connected to VDD. The drain of current mirror output transistor 49 is connected to the source of a P-channel transistor 48, the drain of which is connected by conductor 50 to the drain of a N-channel transistor 47. The source of transistor 47 source is connected to the drain of current mirror output transistor 46. The gates of transistors 47 and 48 are connected to an input conductor 62 of delay cell 40, so transistors 47 and 48 form a first CMOS inverter, the output of which is connected by conductor to one terminal of a capacitor 51, the other terminal of which is connected to ground. Conductor 50 also is connected to the gates of a P-channel transistor 54 and a N-channel 53 which form a second CMOS inverter. The drains of transistors 53 and 54 are connected by conductor 61 to one terminal of a capacitor 61 and to the output 60 of delay cell 40. The other terminal of capacitor 61 is connected to ground. The drain of current mirror output transistor 55 is connected to the source of transistor 54, and the drain of current mirror output transistor 52 is connected to the source of transistor 53.

Increasing the voltage on delay control conductor 29 decreases the delay time of a delay cell by increasing both the capacitor charging current and the capacitor discharging current produced by that delay cell, and similarly, decreasing the voltage on delay control conductor 29 increases the delay time of the delay cell by decreasing both the capacitor charging current and the capacitor discharging current produced by the delay cell.

Referring again to FIG. 5, phase detector 24 of DLL 20 receives the incoming clock signal CKref and the output 22-N of the last delay cell 40-N as its inputs. A pulse of the reference clock signal CKref ripples through delay line 21, creating a different phase delayed clock signal at each delay cell 40-1 through 40-N.

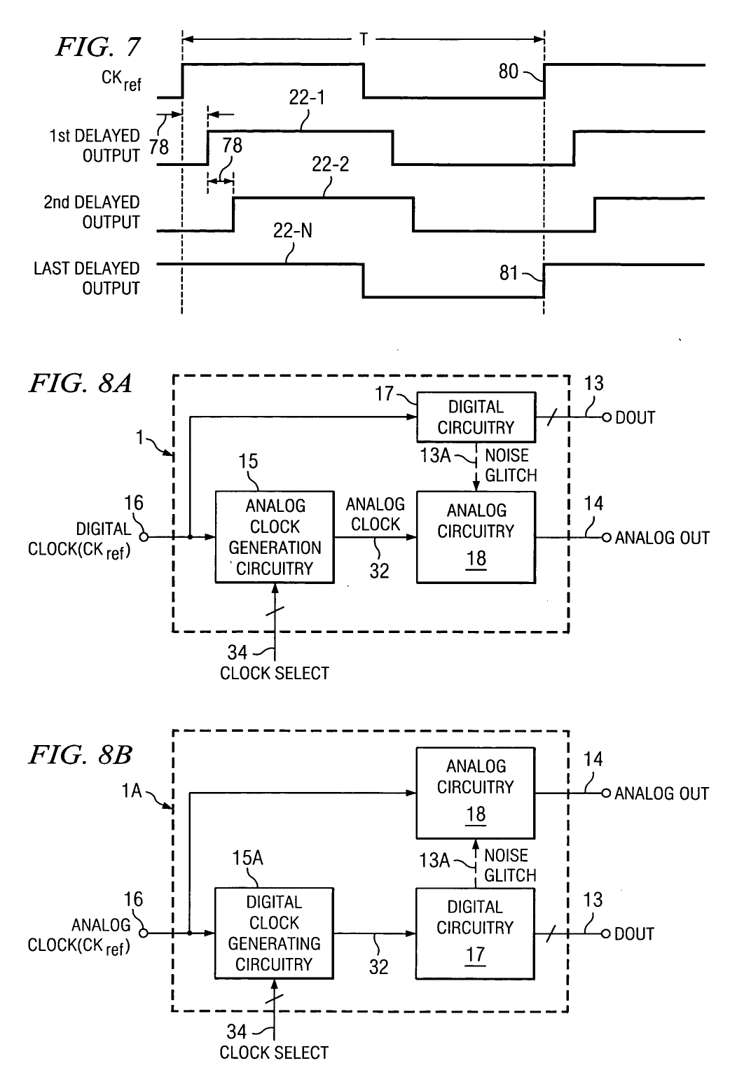

Phase detector 24 compares the arrival of the rising edge 81 in FIG. 7 of the output 22-N of the last delay cell 40-N to the rising edge 80 of the next incoming pulse of CKref. (In some cases, one or both of the edges being compared could be falling rather than rising edges.) If the amount of delay through delay line 21 is too long, such that the delayed pulse on conductor 22-N arrives late, then phase detector 24 produces an UP signal on conductor 25 to cause an increase in the voltage of delay control conductor 29, by causing loop filter 28 to “integrate up” so as to decrease the delay time of delay line 21. Similarly, if the delayed clock signal on conductor 22-N arrives too early, phase detector 24 senses that condition and produces a DOWN signal on conductor 26, which causes loop filter 28 to “integrate down” i.e., decrease the voltage/current of delay control conductor 29, so as to increase the delay time of delay line 21. More specifically, if phase detector 24 senses that the delay through delay line 21 is too long, phase detector 24 produces an UP pulse on conductor 25 and thereby turns on switch 73, causing more charge from current source 72 to flow into capacitor 76 and thereby increase the voltage on delay control conductor 29. A higher control voltage applied to conductor 29 and converted to a corresponding delay control current flowing through the control current input 29A of each delay cell increases the capacitor charging and discharging currents and therefore reduces the delay through each delay cell. The feedback mechanism of DLL 20 locks the output 22-N of last delay cell 40-N in synchronization with the incoming clock CKref delayed by one clock period “T”, as indicated in the timing diagram of FIG. 7.

It should be understood that each of the N delay cells 40 produces a delay precisely equal to T/N, as indicated by reference numerals 78 in FIG. 7, T being the period of CKref, since the total delay through delay line 21 is forced by the feedback to be equal to T. The feedback loop mechanism of DLL 20 is accomplished by continually adjusting the signal on delay control conductor 29 so as to cause the exact delay T through delay line 21 to be locked into DLL 20.

Those skilled in the art will recognize that as long as loop filter 28 has sufficiently high low-frequency gain, the feedback loop can self-adjust without any steady phase error. This causes the delay times of all of the delay cells to be independent of variations in the temperature of the integrated circuit, power supply variations, and integrated circuit manufacturing process variations. This overcomes the previously mentioned variability of the simple delay cells of the prior art. This result is achieved because of the ability of the DLL to adjust the loop filter output voltage to produce the same delay irrespective of operating conditions, temperature variations, power supply variations, integrated circuit manufacturing process variations, etc.

FIG. 8A shows an integrated circuit chip 1 including a mixed signal system of the type referred to above, including digital circuitry 17 and analog circuitry 18, and also including the above described analog clock generating circuitry 15 of FIGS. 4 and 5 for generating an analog clock signal ANALOG CLOCK on conductor 32 which is optimally skewed relative to the timing of DIGITAL CLOCK on conductor 16. In a practical embodiment of invention, digital circuitry 17 and analog circuitry 18 can be included in a delta sigma ADC. The signal DIGITAL CLOCK on conductor 16 is CKref. DIGITAL CLOCK is applied to the input of analog clock generating circuitry 15, which can be the same circuitry shown in FIG. 5, and also is connected to an input of digital circuitry 17. Digital circuitry 17 produces a digital output signal DOUT on bus or conductor 13, and also may produce noise that is synchronized with DIGITAL CLOCK and is coupled to analog circuitry 18, as indicated by dotted line 13A. However, the noise signal is not aligned with any edge of ANALOG CLOCK and therefore does not cause degradation of the operation of analog circuitry 18.

Alternatively, the input reference clock CKref on conductor 16 can be an analog clock signal instead of a digital clock signal, and the derived/optimized clock signal on conductor 32 can be an analog clock signal instead of a digital clock signal. FIG. 8B shows a monolithic chip 1A wherein the signal ANALOG CLOCK on conductor 16 is CKref and is applied to the input of digital clock generating circuitry 15A, which is identical to analog clock generating circuitry 15 of FIG. 8A. ANALOG CLOCK also is connected to an input of analog circuitry 18, which produces an analog output signal ANALOG OUT on conductor 14. Digital clock generating circuitry 15A produces a digital clock signal DIGITAL CLOCK the delay of which is optimally skewed relative to ANALOG CLOCK. DIGITAL CLOCK is applied as an input to digital circuitry 17. Digital circuitry 17 produces a digital output signal DOUT, and also may produce a noise signal that is synchronized with DIGITAL CLOCK and is coupled to analog circuitry 18, as indicated by dotted line 13A. However, the noise signal is not aligned with any edge of ANALOG CLOCK and therefore does not cause degradation of the operation of analog circuitry 18.

The present invention uses DLL 20 to provide multiple delay outputs 22-1, 22-2 . . . 22-N which are fed into a N-to-1 multiplexer 30. The bits 34 of CLOCK SELECT SIGNAL are provided to select one of the N delay cell outputs as an optimally selected analog clock signal on multiplexer output conductor 32. This “programmability” allows engineers to evaluate the system performance for the various delay clock signals produced on delay cell output conductors 22-1 through 22-N and select the one that is considered to be the best, e.g., one that provides the least degradation of the performance of the analog circuitry due to the digital noise coupling from the digital circuitry 17 to the analog circuitry 18.

Thus, the feedback loop through delay line 21, phase detector 24, and loop filter 28 back to delay control conductor 29 operates to lock the rising edge of the output 22-N of the last delay cell 40-N with the rising edge of the next pulse of the reference clock signal CKref, thereby ensuring that the total delay through delay line 21 is precisely equal to the period T of CKref.

Consequently, the feedback loop causes the delay through each delay cell to be independent of various above mentioned parameters (i.e., chip temperature, integrated circuit manufacturing process parameters, power supply voltage) that would otherwise affect the delay through each cell.

While the invention has been described with reference to several particular embodiments thereof, those skilled in the art will be able to make various modifications to the described embodiments of the invention without departing from its true spirit and scope. It is intended that all elements or steps which are insubstantially different from those recited in the claims but perform substantially the same functions, respectively, in substantially the same way to achieve the same result as what is claimed are within the scope of the invention. For example, the CLOCK SELECT inputs 34 of multiplexer 30 could be automatically generated by a computer-controlled system in response to feedback obtained by measurements of the monolithic mixed signal system in order to obtain the optimum skew between the digital and analog clock signals.

What is claimed is:

1. A monolithic integrated circuit mixed signal system comprising:
(a) a digital circuit including a clock input for receiving a digital clock signal;
(b) an analog circuit including an input for receiving an analog clock signal;
(c) clock generation circuitry including a delay locked loop including a N-cell delay line having an input for receiving a reference clock signal and also having a plurality of delay outputs, one of the delay outputs being coupled to an output of the clock generation circuitry, the delay locked loop including a phase detector having a first input coupled to a last delay output of the delay line and a second input coupled to receive the reference clock signal, the delay locked loop also including a loop filter circuit for providing a delay control signal for delay control inputs of the cells of the delay line in response to an output of the phase detector to force a signal delay through the delay line to be equal to a period of the reference clock signal;
(d) the digital circuit causing coupling of a noise glitch to the analog circuit;
(e) the reference clock signal being utilized as one of the digital clock signal and the analog clock signal; and
(f) the output of the clock generation circuitry producing the other of the digital clock signal, the analog clock signal, the analog clock signal and the digital clock signal being skewed from each other to reduce inaccuracy in the analog circuit caused by the coupling of the noise glitch thereto.

2. The monolithic integrated circuit mixed signal system of claim 1 wherein the reference clock signal is the digital clock signal, the output of the clock generation circuitry produces the analog clock signal, and the analog clock signal is delayed relative to the digital clock signal.

3. The monolithic integrated circuit mixed signal system of claim 2 wherein the digital circuit and the analog circuit are included in a delta sigma analog-to-digital converter.

4. The monolithic integrated circuit mixed signal system of claim 1 wherein the phase detector produces first and second signals indicative of whether the signal delay through the delay line is too long or too short, respectively, and wherein the loop filter circuit includes a first current source coupled to a first terminal of a first switch having a second terminal coupled by a delay control conductor to a loop filter capacitor to charge the loop filter capacitor in response to the first signal, and wherein the loop filter circuit includes a second current source coupled to a first terminal of a second switch having a second terminal coupled to the delay control conductor to discharge the loop filter capacitor in response to the second signal.

5. A monolithic integrated circuit mixed signal system comprising:
(a) a digital circuit including a clock input for receiving a digital clock signal;
(b) an analog circuit including an input for receiving an analog clock signal;
(c) clock generation circuitry including
i. a delay locked loop including a N-cell delay line having an input for receiving a reference clock signal and also including a plurality of delay outputs, and
ii. a multiplexer having a plurality of inputs coupled to the plurality of delay outputs, respectively, and a selection input for receiving a selection signal for causing the multiplexer to couple a selected one of the delay outputs to an output of the multiplexer;
(d) the digital circuit causing coupling of a noise glitch to the analog circuit;
(e) the reference clock signal being utilized as one of the digital clock signal and the analog clock signal;
(f) the output of the multiplexer producing the other of the digital clock signal the analog clock signal; and
(g) the selection input signal of the multiplexer causing the analog clock signal and the digital clock signal to be sufficiently skewed from each other to minimize an inaccuracy in the analog circuit caused by the coupling of the noise glitch thereto.

6. The monolithic integrated circuit mixed signal system of claim 5 wherein the delay locked loop includes a phase detector having a first input coupled to a last delay output of the delay line and a second input coupled to receive the reference clock signal, the delay locked loop also including a loop filter circuit for providing a delay control signal for delay control inputs of the cells of the delay line in response to an output of the phase detector to force a signal delay through the delay line to be equal to a period of the reference clock signal.

7. The monolithic integrated circuit mixed signal system of claim 6 wherein the phase detector produces first and second signals indicative of whether the signal delay through the delay line is too long or too short, respectively, and wherein the loop filter circuit includes a first current source coupled to a first terminal of a first switch having a second terminal coupled by a delay control conductor to a loop filter capacitor to charge the loop filter capacitor in response to the first signal, and wherein the loop filter circuit includes a second current source coupled to a first terminal of a second switch having a second terminal coupled to the delay control conductor to discharge the loop filter capacitor in response to the second signal.

8. The monolithic integrated circuit mixed signal system of claim 5 wherein the reference clock signal is the digital clock signal, the output of the clock generation circuitry produces the analog clock signal, and the analog clock signal is delayed relative to the digital clock signal.

9. The monolithic integrated circuit mixed signal system of claim 4 wherein the reference clock signal is the digital clock signal, the output of the clock generation circuitry produces the analog clock signal, and the analog clock signal is delayed relative to the digital clock signal.

10. The monolithic integrated circuit mixed signal system of claim 6 wherein the delay line is a voltage controlled delay line and the delay control signal is a delay control voltage signal.

11. The monolithic integrated circuit mixed signal system of claim 6 wherein each delay cell of the delay line is a current controlled delay cell, the delay locked loop including voltage-to-current conversion circuitry for providing delay control current signals to each current controlled delay cell.

12. The monolithic integrated circuit mixed signal system of claim 9 wherein the digital circuit and the analog circuit are included in a delta sigma analog-to-digital converter.

13. The monolithic integrated circuit mixed signal system of claim 6 wherein the noise glitch is coupled to a ground conductor connected to a first terminal of a sampling capacitor, a second terminal of the sampling capacitor being coupled to an analog signal sampling switch, an opening of the analog signal sampling switch being sufficiently skewed from the digital clock signal to avoid overlapping an occurrence of the noise glitch.

14. A method of operating a mixed signal system in an integrated circuit chip to avoid degradation of an analog signal due to noise caused by a digital signal, the mixed signal system including a digital circuit including a clock input for receiving a digital clock signal and also including an analog circuit including a clock input for receiving an analog clock signal wherein a digital signal associated with the digital circuitry causes coupling of a noise glitch to the analog circuit, the method comprising:
(a) applying a reference clock signal to a clock input of a delay locked loop having a plurality of delay outputs,
(b) operating the delay locked loop in response to the reference clock signal to force a signal delay time through a delay line of the delay locked loop to be equal to a period of the reference clock signal;
(b) coupling one of the delay outputs to an output of the delay locked loop; and
(c) using the reference clock signal as one of the digital clock signal and the analog clock signal, the output of the multiplexer producing the other of the digital clock signal and the analog clock signal, the analog clock signal and the digital clock signal being sufficiently skewed from each other to minimize an inaccuracy in the analog circuit caused by the coupling of the noise glitch thereto.

15. A method of operating a mixed signal system in an integrated circuit chip to avoid degradation of an analog signal due to noise caused by a digital signal, the mixed signal system including a digital circuit including a clock input for receiving a digital clock signal and also including an analog circuit including a clock input for receiving an analog clock signal, wherein a digital signal associated with the digital circuitry causes coupling of a noise glitch to the analog circuit, the method comprising:
(a) applying a reference clock signal to a clock input of a delay locked loop having a plurality of delay outputs;
(b) coupling the plurality of delay outputs to a plurality of inputs, respectively, of a multiplexer having a selection input for receiving a selection signal for causing the multiplexer to couple a selected one of the delay outputs to an output of the multiplexer;
(c) using the reference clock signal as one of the digital clock signal and the analog clock signal, the output of the multiplexer producing the other of the digital clock signal and the analog clock signal; and
(d) providing the selection input signal of the multiplexer so as to cause the analog clock signal and the digital clock signal to be sufficiently skewed from each other to minimize an inaccuracy in the analog circuit caused by the coupling of the noise glitch thereto.

16. The method of claim 15 including operating the delay locked loop in response to the reference clock signal to force a signal delay time through a delay line of the delay locked loop to be equal to a period of the reference clock signal.

17. The method of claim 15 including manually selecting values of the selection input to couple a selected delay output to an output of the multiplexer in order to minimize the inaccuracy.

18. The method of claim 15 including operating a computer system to select values of the selection input to couple corresponding delay outputs to an output of the multiplexer in response to measured values of the inaccuracy.

19. A mixed signal system in an integrated circuit chip, comprising:
(a) a digital circuit including a clock input for receiving a digital clock signal and also including an analog circuit including a clock input for receiving an analog clock signal, wherein a digital signal associated with the digital circuitry causes coupling of a noise glitch to the analog circuit;
(b) means for applying a reference clock signal to a clock input of a delay locked loop having a plurality of delay outputs;
(c) means for coupling one of the delay outputs to an output of the delay locked loop; and
(d) means for using the reference clock signal as one of the digital clock signal and the analog clock signal, the output of the multiplexer producing the other of the digital clock signal and the analog clock signal, the analog clock signal and the digital clock signal being sufficiently skewed from each other to minimize an inaccuracy in the analog circuit caused by the coupling of the noise glitch thereto.

20. A mixed signal system in an integrated circuit chip, comprising:
(a) a digital circuit including a clock input for receiving a digital clock signal and also including an analog circuit including a clock input for receiving an analog clock signal, wherein a digital signal associated with the digital circuitry causes coupling of a noise glitch to the analog circuit;
(b) means for applying a reference clock signal to a clock input of a delay locked loop having a plurality of delay outputs;
(c) means for coupling one of the delay outputs to an optimized clock conductor in response to a selection signal;
(d) means for using the reference clock signal as one of the digital clock signal and the analog clock signal, the optimized clock conductor providing the other of the digital clock signal and the analog clock signal; and
(e) means for providing the selection input signal of the multiplexer so as to cause the analog clock signal and the digital clock signal to be sufficiently skewed from each other to minimize an inaccuracy in the analog circuit caused by the coupling of the noise glitch thereto.
